(19) United States
(12) Patent Application Publication
(10) Pub. No.: US 2019/0312213 A1
(43) Pub. Date: Oct. 10, 2019

(54) ORGANIC ELECTROLUMINESCENT MATERIAL AND APPLICATION THEREOF

(71) Applicant: Dalian University of Technology, Dalian (CN)

(72) Inventor: Di Liu, Dalian (CN)

(21) Appl. No.: 16/373,658

(22) Filed: Apr. 3, 2019

(30) Foreign Application Priority Data
Apr. 4, 2018 (CN) 201810300407.4

(51) Int. Cl. H01L 51/00

(52) U.S. Cl. CPC H01L 51/0072; H01L 51/5016; H01L 51/0067

(57) ABSTRACT

The present disclosure provides organic electroluminescent material m-BPySCz and application thereof, which is a compound with a structure of Formula I. The compound is a bipolar host material characterized by high efficiency and slow decay. Compared to most of the small molecular materials described in prior art, the compound m-BPySCz exhibits slow decay at high brightness in both of blue light-emitting device and green light-emitting device. Therefore, the organic electroluminescent material has wide application prospect in preparation of electroluminescent devices.

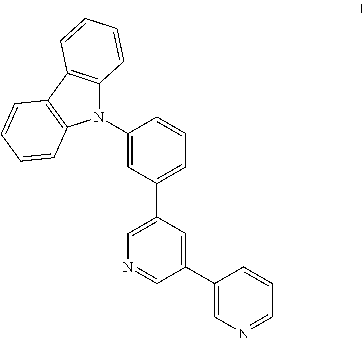 [SMILES: c1cncc(-c2cncc(-c3cccc(-n4c5ccccc5c5ccccc54)c3)c2)c1]

### CROSS REFERENCE TO RELATED APPLICATIONS

The present application claims the benefit of Chinese Patent Application No. 201810300407.4 filed on Apr. 4, 2018, the contents of which are incorporated herein by reference in their entirety.

### FIELD OF THE DISCLOSURE

The disclosure belongs to the technical field of electroluminescent materials and relates to a new type of carbazole electroluminescent material.

### BACKGROUND OF THE DISCLOSURE

The 21^{st} century has been called as new “electronic information age”. Demand for information by people is increasing with the development of internet. Smart phones, watches and (flat-panel) computers have been an indispensable part of people's daily life. As the information age has arrived, a development of display technology is greatly promoted. With pursuit of large-size and flexible displays with lighter weight, thinner thickness and more energy-saving, organic electroluminescent have been mainstream of market. A process of an active material arising light-emitting under the influence of an electric field is called as electroluminescence (EL). When the active material is organism, the process is called as organic EL, that is, an organic light-emitting diode (OLED). The organic light-emitting diode has advantages of low voltage driving (3˜10V), self-luminous pixel point, fast response, wide viewing angle and thin thickness, and is a solid-state full-color display that can be processed by a flexible substrate and covers the entire visible spectrum. In terms of processing technology, it is possible to manufacture large-area panels by inkjet printing or spin coating process, which greatly reduces manufacturing costs and becomes a hot spot in the field of display technology research. In short, this is an era of the OLED industry.

To achieve full color display and white lighting, red, green and blue electroluminescent materials with good color purity, high luminous efficiency and good film-forming properties are required. At present, electroluminescent materials are mainly divided into three types: the first-generation of fluorescent material, the second-generation of phosphorescent materials and the third-generation of delayed fluorescent materials. The phosphorescent materials contain heavy metal atoms such as Ir(III), Pd(II), Pt(II), Os(II), Ru(II), and emit light through charge transfer process of transiting metal icon to ligand (³MLCT) state. Since 25% of singlet excitons and 75% of triplet excitons can be used simultaneously, the theoretical ηᵢₙₜ reaches 100%. These metal complexes have the advantages of high brightness, high efficiency, wide illuminating color coverage, etc., and thus have become the object of intense research by scientists at home and abroad, and are currently the most widely used electroluminescent materials.

Phosphorescent organic light-emitting diodes (PhOLEDs) containing phosphorescent dyes have attracted attention because they can utilize both singlet and triplet excitons to achieve an internal quantum efficiency of 100%. In PhOLED, the luminescent layer is doped in a host-guest form, that is, the phosphorescent dye (guest) is doped into a host material having a certain carrier transporting ability, thereby reducing the triplet-triplet annihilation (TTA), concentration quenching, triplet-polaron quenching (TPQ), and the like caused by the long lifetime of the triplet excitons. Therefore, the host material and the phosphorescent dye together determine device performance. The bipolar host material has both an electron transporting group (n-type group) and a hole transporting group (p-type group), which facilitates carrier transport balance in the light emitting layer, thereby improving device efficiency. More importantly, for the same guest material, choosing different host materials, especially bipolar host materials, can significantly improve device efficiency and slow down efficiency decay.

Carbazole, due to its high triplet energy (3.0 eV), excellent hole transport properties and small singlet-triplet energy difference (ΔEST=0.48 eV), is used as p-type group in bipolar host materials. These advantages enable a lower driving voltage to be obtained when a carbazole-containing host material is used in a PhOLED. However, for most organic semiconductor materials, the hole mobility of the p-type group is much larger than that of the n-type group, resulting in a serious problem of carrier transport imbalance in the device light-emitting layer. Pyridine groups are often used in the design of electron transport materials such as TmPyPB and BmPyPB. Therefore, the use of pyridine as an n-type group for the design of bipolar host materials facilitates carrier balance throughout the device. However, such materials, especially small molecule carbazole bipolar host materials, are often difficult to achieve at the same time in both efficiency and growth decay cycles.

### SUMMARY OF THE DISCLOSURE

One of the purposes of the disclosure is to provide a new type of bipolar host material with slow efficiency decay.

The organic electroluminescent material described in the disclosure is a compound having the structure of formula I:

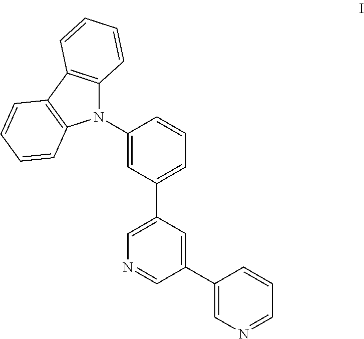 [SMILES: c1cncc(-c2cncc(-c3cccc(-n4c5ccccc5c5ccccc54)c3)c2)c1]

The above compound of the disclosure is a bipolar host material with high efficiency and slow decay. In comparison with the small molecular materials described in prior art, this compound m-BPySCz exhibited slower decay at high brightness in both of blue light-emitting device and green light-emitting device.

Based on the above outstanding characteristics, the disclosure further provides the application of an organic electroluminescent material in the preparation of electroluminescent devices. In embodiments, it can be applied to various kinds of electroluminescent devices. In those application, it is especially used to organic electroluminescent diodes.

Furthermore, the disclosure provides an organic electroluminescent device, including a light-emitting layer that contains the above organic electroluminescent material in this disclosure.

### BRIEF DESCRIPTION OF THE DRAWINGS

FIG. 1 is molecular stacking diagram of compound m-BPySCz.

FIG. 2 (a) is uv-visible absorption spectra and fluorescence emission spectra of compound m-BPySCz in dichloromethane solution.

FIG. 2 (b) is uv-visible absorption spectra and fluorescence emission spectra of compound m-BPySCz in thin film.

FIG. 3 is phosphorescence spectra of compounds m-BPyDCz and m-BPySCz.

FIG. 4 is cyclic voltammogram of compound m-BPySCz.

FIG. 5 (a) is current density-voltage-brightness curve of sky-blue light-emitting device B.

FIG. 5 (b) is efficiency curve of the sky-blue light-emitting device B.

FIG. 6 is electroluminescence spectrum of the sky-blue light-emitting device B.

FIG. 7 is external quantum efficiency-brightness curve of sky-blue light-emitting device B.

FIG. 8 (a) is current density-voltage-brightness curve of the green light-emitting device G.

FIG. 8 (b) is efficiency curve of the green light-emitting device G.

FIG. 9 is electroluminescence spectrum of the green light-emitting device G.

FIG. 10 is external quantum efficiency-brightness curve of the green light-emitting device G.

### DESCRIPTION OF THE PREFERRED EMBODIMENTS

The disclosure provides a compound m-BPySCz having structure of formula I as an organic electroluminescent material:

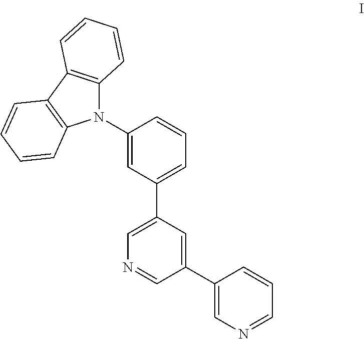 [SMILES: c1cncc(-c2cncc(-c3cccc(-n4c5ccccc5c5ccccc54)c3)c2)c1]

The compound m-BPySCz was synthesized according to the following preparation route:

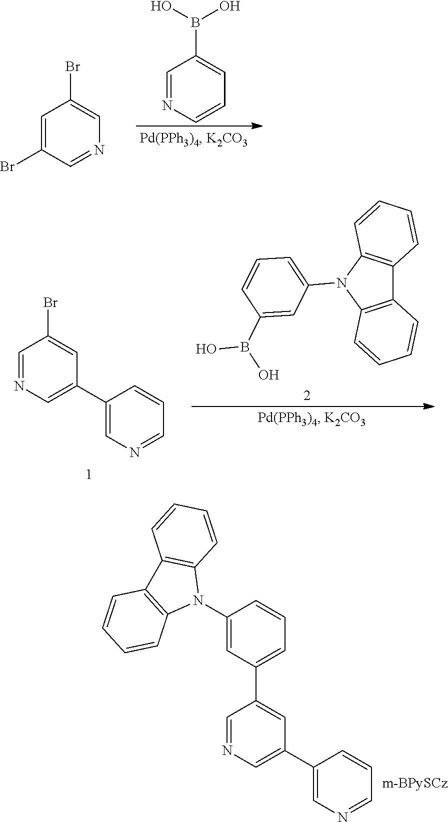 [SMILES: Brc1cncc(Br)c1 ; OB(O)c1cccnc1 ; Brc1cncc(-c2cccnc2)c1 ; OB(O)c1cccc(-n2c3ccccc3c3ccccc32)c1 ; c1cncc(-c2cncc(-c3cccc(-n4c5ccccc5c5ccccc54)c3)c2)c1]

The synthesis method of compound m-BPySCz includes the following steps:

### (1) Synthesis of Intermediate 1

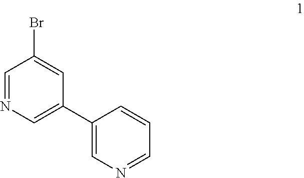 [SMILES: Brc1cncc(-c2cccnc2)c1]

A mixture of pyridine-3-boric acid (123 mg, 1 mmol), 3,5-dibromopyridine (469 mg, 2 mmol), toluene, ethanol, potassium carbonate aqueous solution (1.5 mL, 3 mmol) and tetrakis (triphenylphosphine) palladium (57 mg, 0.05 mmol) was refluxed under nitrogen atmosphere for 12 hours at 80° C. After the reaction ended, cooling to room temperature and filtration. The filtrate was diluted with 18 mL deionized water to separate the organic layer, and the aqueous phase (3×18 mL) was extracted with dichloromethane. The combined organic solution was dried and concentrated under reduced pressure. The obtained residue was isolated by column chromatography using petroleum ether and ethyl acetate (v:v=7:1) as the mobile phase to produce pure compound 1 as white solid.

1: yield 75%_{°} ¹H NMR (500 MHz, CDCl₃): δ 8.84 (dd, J=1.5, 0.5 Hz, 1H), 8.76 (d, J=2.0 Hz, 1H), 8.73 (d, J=2.0 Hz, 1H), 8.70 (dd, J=3.0, 2.0 Hz, 1H), 8.04 (t, J=2.0 Hz, 1H), 7.88 (dq, J=4.0, 1.5 Hz, 1H), 7.44 (qd, J=4.0, 1.0 Hz, 1H). TOF-EI-MS (m/z): calcd for C₁₀H₇BrN₂ 233.9793; found, 233.9790 [M]⁺.

### (2) Synthesis of Intermediate 2

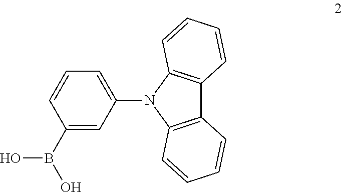 [SMILES: OB(O)c1cccc(-n2c3ccccc3c3ccccc32)c1]

A mixture of Carbazole (1.67 g, 10 mmol), 1,3-dibromobenzene (3.1 g, 10 mmol), potassium carbonate (556 mg, 4 mmol), cuprous iodide (48 mg, 0.25 mmol), 1,10-phenanthroline (45 mg, 0.25 mmol) in dry N,N-dimethylformamide (DMF) was stirred under N₂ at 165° C. for 24 hours. After removing the solvent, the residue was isolated by silica gel column chromatography with petroleum ether and ethyl acetate (v:v=5:1) as the mobile phase to produce 1-bromo-3-(9H-carbazole) benzene. Under nitrogen atmosphere, a solution of 1-bromo-3-(9H-carbazole) benzene (963 mg, 3 mmol) in anhydrous tetrahydrofuran was treated by liquid nitrogen, and was added slowly n-butyl lithium 2.5 mL (4 mmol). Then trimethyl borate (1 mL, 1 mmol) was added and the mixture was warmed to room temperature to react for 12 h. After adding 20 mL deionized water and separated, the water phase was extracted with dichloromethane (3×18 mL). Then the combined organic solution was concentrated under reduced pressure and the residue was isolated by column chromatograph with petroleum ether and ethyl acetate (v:v=10:1) as mobile phase to produce pure intermediate 2.

### (3) Synthesis of Compound m-BPySCz

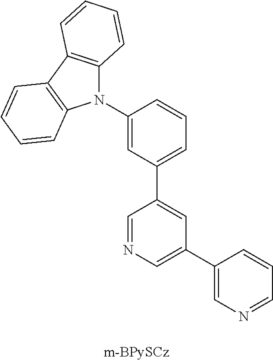 [SMILES: c1cncc(-c2cncc(-c3cccc(-n4c5ccccc5c5ccccc54)c3)c2)c1]

A mixture of compound 1 (235 mg, 1 mmol), 2 (287 mg, 1 mmol), toluene, ethanol, potassium carbonate aqueous solution (1.5 mL, 3 mmol) and tetrakis (triphenylphosphine) palladium (57 mg, 0.05 mmol) was refluxed under N₂ at 80° C. for 12 hours. Upon cooling and adding with water, the mixture was separated and the aqueous phase was extracted with dichloromethane (3×18 mL). The combined organic solution was concentrated under reduced pressure and the residue was isolated by column chromatograph using petroleum ether and ethyl acetate (v:v=3:1) as the mobile phase and further recrystallized in chloroform/methanol to give the final target product in-BPySCz.

m-BPySCz: White solids, yield 75%. ¹H NMR (500 MHz, CDCl₃): δ 8.97 (s, 1H), 8.92 (s, 1H), 8.87 (s, 1H), 8.70 (d, J=3.5 Hz, 1H), 8.16 (d, J=8.0 Hz, 2H), 8.10 (t, J=2.0 Hz, 1H), 7.97 (dt, J=4.0, 1.5 Hz 1H), 7.87 (d, J=1.5 Hz, 1H), 7.78-7.76 (m, 2H), 7.68 (dt, J=3.0, 2.0 Hz, 1H), 7.48-7.42 (m, 5H), 7.32 (td, J=6.0, 1.5 Hz, 2H). ¹³C NMR (126 MHz, CDCl₃): δ 149.56, 148.27, 147.82, 147.40, 140.76, 139.35, 138.79, 135.97, 134.59, 133.72, 133.28, 132.92, 130.83, 127.06, 126.22, 126.12, 125.84, 123.85, 123.53, 120.46, 120.23, 109.63. TOF-EI-MS (m/z): calcd for C₂₈H₁₉N₃ 397.1579; found 397.1590 [M]⁺.

The following non-limiting examples, in conjunction with the accompanying drawings, are used to further illustrate the physical and chemical properties of the electroluminescent material m-BPySCz of the present disclosure and its beneficial effects, and should not be construed as limiting the scope of the present disclosure.

### Example 1. Single Crystal Structure Analysis of Compound m-BpySCz by X-Ray Diffraction

The single crystal of compound m-BPySCz was developed in methanol/tetrahydorfuran by solvent diffusion technique, and the crystal structure of m-BPySCz was analyzed by X-Ray single crystal diffraction method, thus space arrangement sequences of m-BPySCz were confirmed. The main data of crystal structure are shown in Table 1.

TABLE 1
Crystal parameters of compound m-BPySCz

| Compound | m-BPySCz |
|---|---|
| formula | C₂₈H₁₉N₃ |
| fw | 397.46 |
| T (K) | 298(2) K |
| crystal system | Monoclinic |
| space group | P2(1)/n |
| a (Å) | 14.3706(11) |
| b (Å) | 4.0501(3) |
| c (Å) | 33.246(3) |
| V (Å³), Z | 1932.6(3), 4 |
| F (000) | 832 |
| crystal size (mm³) | 0.25 × 0.19 × 0.09 |
| Rint | 0.0260 |
| ρ_{c} (Mg/m³) | 1.366 |
| μ (mm⁻¹) | 0.081 |
| goodness-of-fit on F² | 1.065 |
| R₁, ^{a}wR₂^{b} [I > 2σ(I)] | 0.0367, 0.0950 |

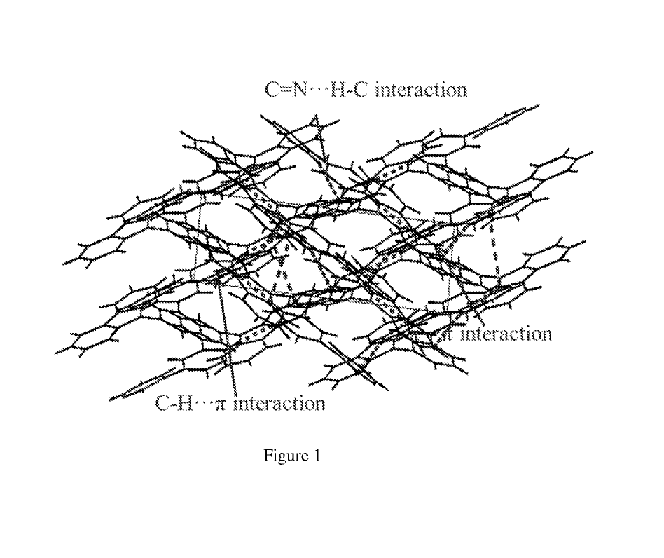

The molecular stacking diagram of the compound m-BPySCz was analyzed by Diamond software, as shown in FIG. 1. It can be seen that in the compound m-BPySCz, a meta substitution is used between any two adjacent groups, so that a single molecule exhibits a “Zigzag” conformation, and the main forces between the molecules are CH . . . π and C═N . . . HC hydrogen bond, this hydrogen bond force is favorable for film stability after vapor deposition film formation. Due to the “Zigzag” spatial molecular configuration, the carbazole group of m-BPySCz is linked to the terminal pyridine in the adjacent m-BPySCz via the CH . . . π hydrogen bond (3.09 Å); the pyridylene group is interlocked with the pyridyl group of the adjacent molecule by the C═N . . . HC hydrogen bond, so that the whole forms a staggered three-dimensional grid stacking mode. This relatively tightly intertwined network structure not only facilitates the transport of carriers between the bodies, but also mitigates the interaction between the host and the host or doped objects, thereby slowing the exciton annihilation.

### Example 2: Photophysical Property

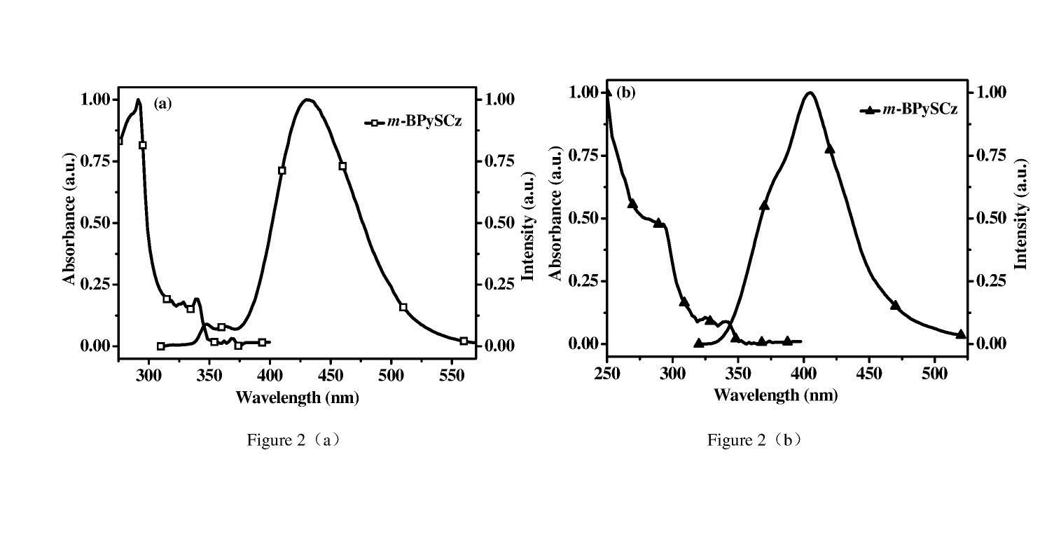

The UV-visible absorption spectrum and fluorescence spectrum of m-BPySCz at room temperature were determined by using dry dichloromethane (DCM) as solvent and the concentration of solution was 1×10⁵ mol/L at room temperature, as shown in FIG. 2 (a). The strong absorption band around 290 nm can be attributed to the π-π* electronic transition absorption from the center of the carbazole group, and the absorption band at the long wavelength of 310-350 nm can be attributed to the n-π* electron transition absorption of the carbazole-coordinated yoke group. The solid film was vacuum-deposited on a quartz substrate, and the ultraviolet-visible absorption spectrum and the fluorescence spectrum of the m-BPySCz film state were measured at room temperature, as shown in FIG. 2(b). With an excitation wavelength of 290 nm, the fluorescence spectrum of m-BPySCz in the film exhibits a pure blue light emission with an emission peak wavelength of 402 nm.

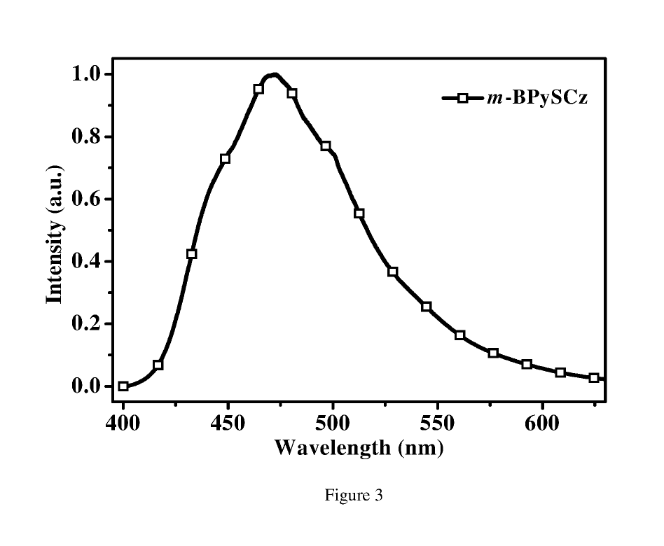

In doped structural devices, the triplet energy (ET) of the host material is important for energy transfer and for limiting triplet excitons. The phosphorescence spectrum and photoluminescence spectrum of m-BPySCz were measured in glassy 2-methyltetrahydrofuran (2-MeTHF) at 77 K, as shown in FIG. 3. Based on the wavelength corresponding to the highest energy vibration band in the phosphorescence spectrum, the ET of m-BPySCz is calculated to be 2.84 eV. The relevant parameters of photophysical properties are shown in Table 2.

TABLE 2
Physical property data of compounds m-BPyDCz and m-BPySCz

| Compound | λ_{abs}^{a} | λₘₐₓ^{ema} | E_{T} | HOMO/LUMO |
|---|---|---|---|---|
| m-BPySCz | 291, 327, 340 | 402 | 2.84 | −5.58/−2.43 |

Footnote:
^{a}in thin film, the corresponding absorption and emission peaks inuv-visible absorption spectra and fluorescence emission spectra.

### Example 3: Electrochemical Property Research

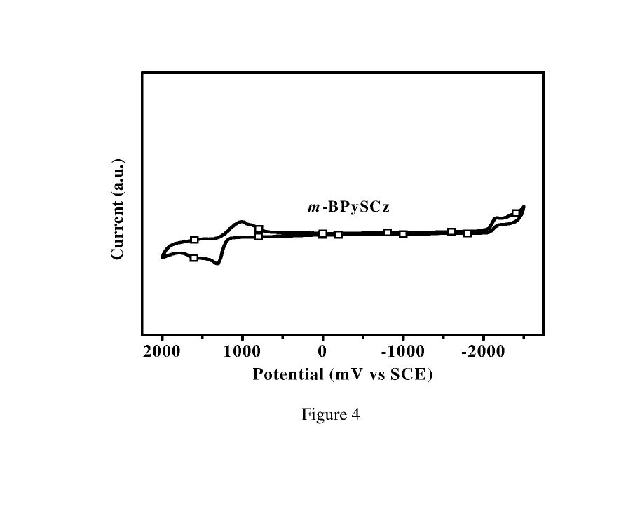

The cyclic voltammetry (CV) was measured on BAS100 type electrochemical analyzer for m-BPySCzin degassed and dry dichloromethane and N,N-dimethylformamide solutions at a scanning rate of 100 mV/s, with Bu₄NPF₆ as electrolyte. The voltammograms are shown in FIG. 4. The HOMO and LUMO levels of m-BPySCz are calculated from the onset potentials of the first oxidation and reduction wave as −5.58 eV and −2.43 eV, respectively, according to the equations of E_{HOMO}=−e(Eₒₓ^{onset}+4.4) and E_{LUMO}=−e(Eₒₙₛₑₜᵣₑₓ+4.4). The relevant electrochemical data are summarized in Table 2.

### Example 4: Electroluminescence Properties Research

m-BPySCz was used as host material to fabricated sky-blue phosphorescence OLEDs by doping FIrpic in emitting layer, the device structure was same as those in previous report in ACS Appl. Mater. Interfaces 2017, 9, 37888-37897. PEDOT:PSS and LiF were used as hole and electron injecting material, TAPC and TmPyPB as hole and electron transporting layer, and a thin layer (5 nm) of TCTA as a second hole transporting and exciton blocking layer. All electroluminescence parameters are shown in Table 3.

TABLE 3
Electroluminescence data of sky-blue light-emitting devices (B) and greenlight-emitting
devices (G)

| | | Vₒₙ | Lₘₐₓ | η_{c}^{a, b} | ηₚ^{a} | ηₑₓₜ^{a, b} | CIE |
|---|---|---|---|---|---|---|---|
| Device | Host | (V) | (cd/m²) | (cd/A) | (lm/W) | (%) | (x, y) ^{c} |
| B | m-BPySCz | 2.9 | 26962 | 50.3, 45.3 | 43.5 | 27.3, 25.1 | 0.14, 0.30 |
| G | m-BPySCz | 2.7 | 116600 | 97.9, 92.6 | 102.5 | 28.0, 26.7 | 0.28, 0.64 |

In Table 3:
a: maximum efficiency of the device;
b: efficiency at a brightness of 1000 cd/m²
c: CIE at 7 V

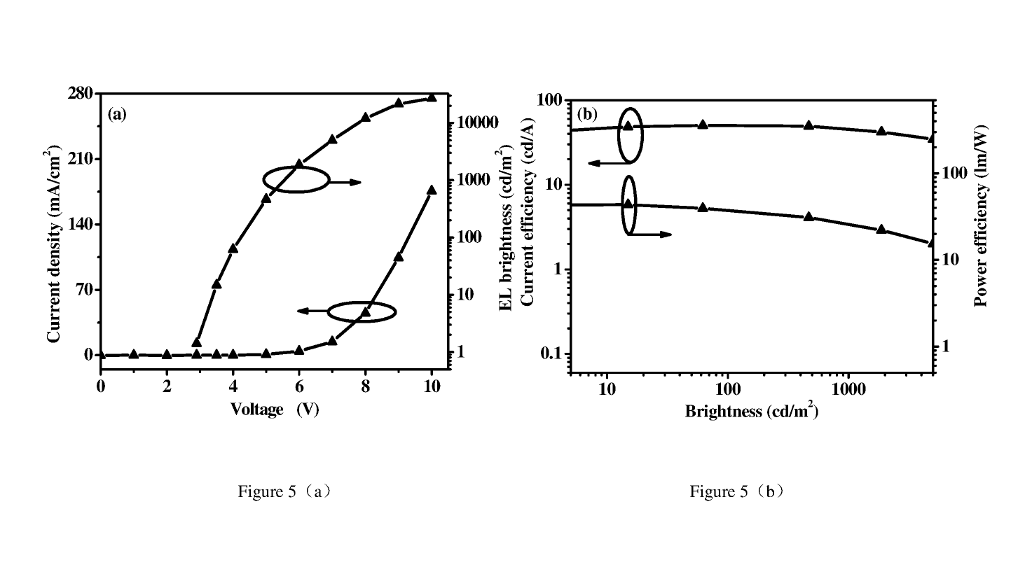

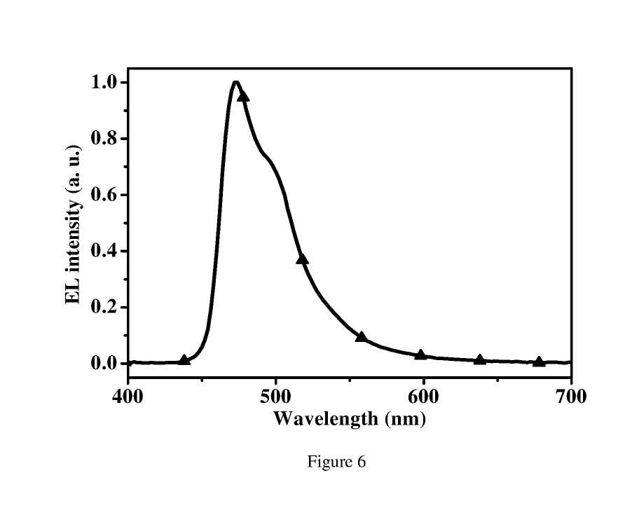

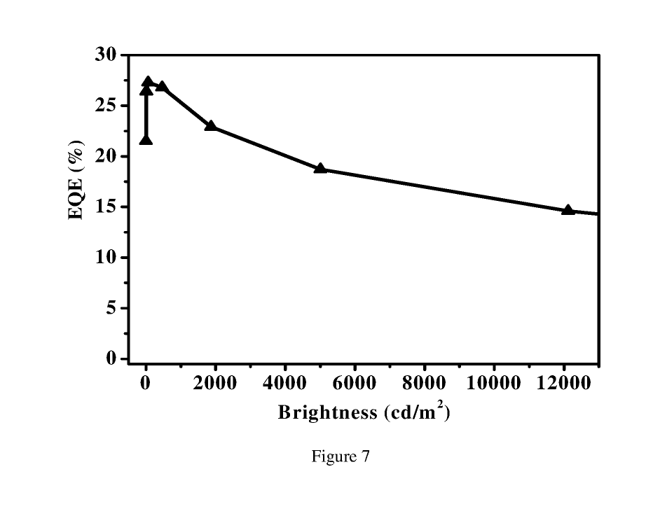

The current density-voltage-brightness (J-V-B) characteristics and efficiency curve of sky-blue OLED B are shown in FIG. 5 (a) and FIG. 5 (b), and the electroluminescence spectra of device B is shown in FIG. 6. Device B turned on (to delivered a brightness of 1 cd/m²) at a voltage of 2.9 v, and exhibited a maximum external quantum efficiency (η_{ext,max}) of 27.3%, and the maximum current efficiency (η_{c,max}) and the power efficiency (η_{p,max}) of 50.3 cd/A and 43.5 lm/W, respectively. In recent years, Ma, Lee, Li and Wong reported device data of 27.5% (49.4 cd/A), 31.4% (53.1 cd/A), 25.3% (55.6 cd/A) and 26.4% (57.6 cd/A) respectively, representing the best efficiencies of similar structure devices with FIrpic as doped emitter to date. It is obvious that the efficiencies of m-BPySCz hosted blue devices (27.3%, 50.3 cd/A) are among the best data described in prior art. In addition, this blue device B is characterized by slow efficiency roll-off. For example, under the practical brightness of 1000 cd/m², device B still maintains the external quantum efficiency of 25.1% (FIG. 7), corresponding to the efficiency roll-off of only 8.05% from the maximum value. The slow efficiency decay is ascribed to the 3D grid stacking style of host m-BPySCz in its film due to its unique “Zig-zag” conformation, which not only guarantees charge balance by ordered carbazole and pyridine channels, but also suppresses exciton quenching by relatively large intermolecular distances.

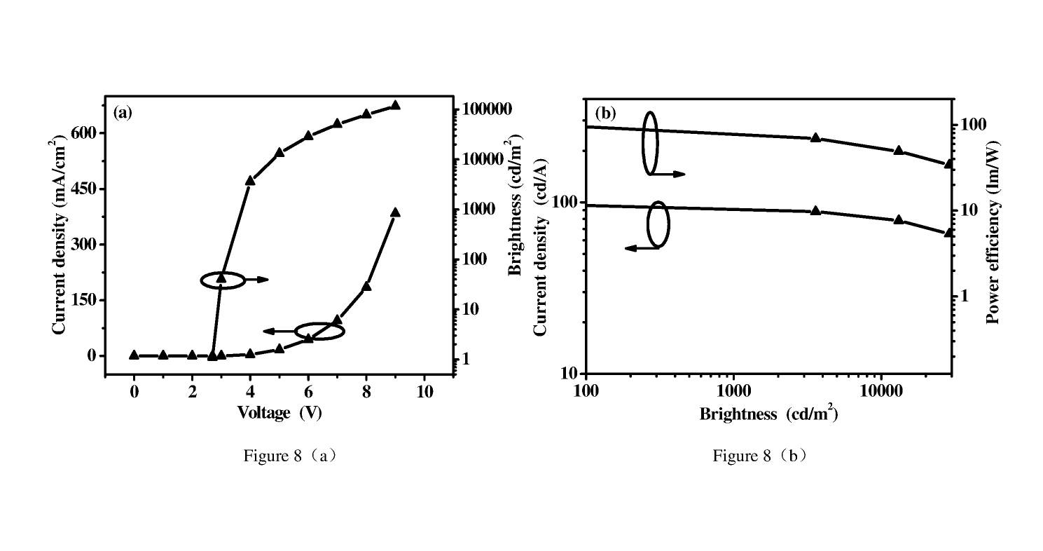

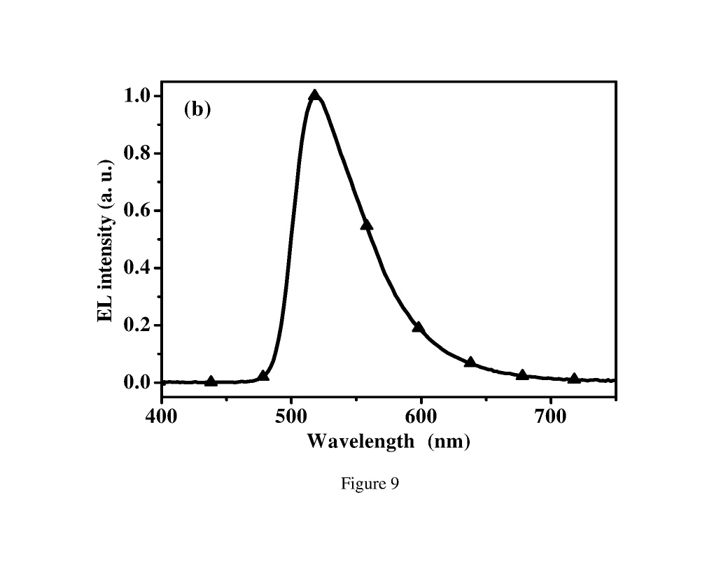

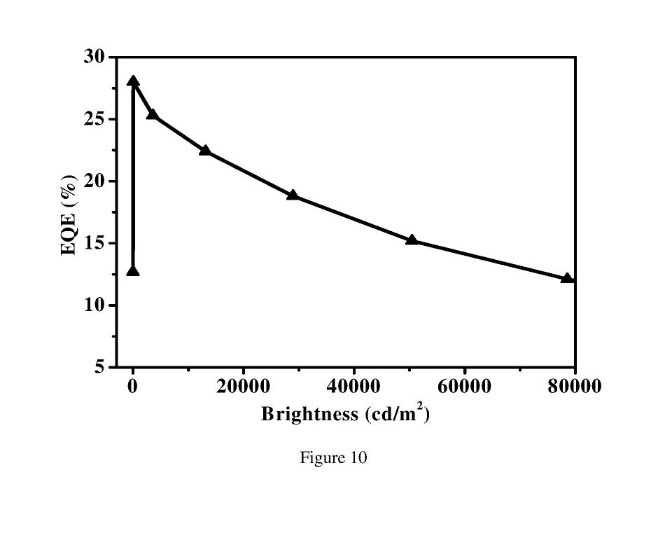

In order to further study the properties of m-BPySCz as the host material of the green PhOLED, device G uses the same structure as the sky-blue light-emitting device, with 8 wt % of Ir(ppy)3 as the guest. The J-V-B curve and efficiency curve are shown in FIGS. 8(a) and 8(b), and all electroluminescence parameters are summarized in Table 3. Since the triplet energy of Ir(ppy)3 is low (2.40 eV), the triplet excitons in the luminescent layer of the green light-emitting device can be completely confined in Ir(ppy)3, so that the device G exhibits a CIE coordinate of (0.30, 0.63) of green light emission, and no emission peaks from the bulk or adjacent layer material were found (FIG. 9). The turn-on voltage of device G is 2.7 V, η_{ext,max} is 28.0%, η_{c,max} is 97.9 cd/A, and η_{p,max} is 102.5 lm/W. In recent years, Kido and Li respectively reported the data of the green light-emitting device, with light efficiency of 24% (128 lm/W, 84 cd/A), 28% (105 lm/W, 100 cd/A), and 27.3% (96.1/1 m W, 91.8) and 28.2% (102.8 lm/W, 98.2 cd/A), representing the best efficiency values of similar structural devices with Ir(ppy)3 as the guest material so far. It can be seen that the efficiency of the green light-emitting device G with m-BPySCz as the main material in the zigzag conformation is 28.0% (102.5/1 m W, 97.9 cd/A), which is comparable to the optimal data. Even in practical applications of 1000 cd/m², G2 still exhibits an external quantum efficiency of 26.7%, which is only 4.6% attenuated with respect to maximum efficiency, and its external quantum efficiency still reached 24.0% at 10,000 cd/m² of extremely high brightness (FIG. 10).

### Example 7: Comparison with Prior Art

(1) The data of unencapsulated devices emitting blue light, the result of comparison as following Table 4:

TABLE 4

| | η_{ext, max} | η_{ext, 1000} | Δη₁₀₀₀ | |
|---|---|---|---|---|
| Host | (%) | (%) | (%) | References |
| m-BPySCz | 27.3 | 25.1 | 8.05 | Present disclosure |
| PCPO5 | 31.4 | 28.6 | 8.9 | Adv. Funct. Mater. 2014, 24, |
| | | | | 4164-4169 |
| p-PyPOmCP | 19.1 | 16.7 | 12.6 | Chem. Sci., 2016,7, 6706-6714 |
| PCz-BFP | 23.0 | 20.0 | 13.0 | Adv. Mater. 2012, 1-5 |
| o-CzCzCN | 21.0 | 18.0 | 14.3 | J. Mater. Chem. C, 2013, 1, |
| | | | | 8140 |
| CzT | 9.9 | 8.3 | 16.2 | J. Mater. Chem., 2012, 22, 3832- |
| m-CzPyPz | 24.5 | 20.5 | 16.3 | ACS Appl. Mater. Interfaces |
| | | | | 2016, 8, 22382-22391 |
| pTCSPO | 5.5 | 4.6 | 16.4 | Adv. Funct. Mater. 2012, 22, |
| | | | | 2830-2836 |
| BCPO | 23.5 | 19.4 | 17.4 | Adv. Mater. 2010, 22, |
| | | | | 2468-2471 |
| m-CzCzCN | 16.4 | 13.5 | 17.7 | J. Mater. Chem. C, 2013, 1, |
| | | | | 8140 |
| pDCSPO | 7.6 | 6.1 | 19.7 | Adv. Funct. Mater. 2012, 22, |
| | | | | 2830-2836 |
| PyA-BP | 15.1 | 12.0 | 20.5 | Chem Asian J, 2012, |
| | | | | 7(10): 2203-2207 |
| CSPO | 9.1 | 7.0 | 23.1 | Adv. Funct. Mater. 2012, 22, |
| | | | | 2830-2836 |
| mCPDPz | 16.8 | 12.8 | 23.8 | ACS Appl. Mater. Interfaces |
| | | | | 2015, 7, 26206-26216 |
| STzDCz | 25.0 | 18.8 | 24.8 | J. Mater. Chem. C, 2016,4, |
| | | | | 7260-7268 |
| 3-CzDPz | 19.54 | 14.6 | 25.3 | ACS Appl. Mater. Interfaces |
| | | | | 2015, 7, 26206-26216 |
| PyA-PCz | 14.5 | 10.5 | 27.6 | Chem Asian J, 2012, 7(10) |
| | | | | 2203-2207 |
| ICDP | 10.4 | 7.4 | 28.8 | Adv. Funct. Mater. 2015, 25, |
| | | | | 5548-5556 |
| o-CzDPz | 25.6% | 18.2 | 28.9 | ACS Appl. Mater. Interfaces |
| | | | | 2015, 7, 26206-26216 |
| BCzPh | 14.4 | 9.9 | 31.3 | J. Mater. Chem. C, 2013, 1, |
| | | | | 8177-8185 |
| o-CzPyPz | 17.4 | 11.8 | 32.2 | ACS Appl. Mater. Interfaces |
| | | | | 2016, 8, 22382-22391 |
| m-CzDPz | 26.2 | 17.0 | 36.1 | ACS Appl. Mater. Interfaces |
| | | | | 2015, 7, 26206-26216 |
| 4ICPPy | 11.7 | 7.1 | 39.3 | Adv. Funct. Mater. 2015, 25, |
| | | | | 5548-5556 |
| m-PyPOmCP | 25.3 | 13.8 | 45.5 | Chem. Sci., 2016,7, 6706-6714 |
| p-CzPyPz | 25.3 | 10.9 | 56.9 | ACS Appl. Mater. Interfaces |
| | | | | 2016, 8, 22382-22391 |
| 4ICDPy | 18.4 | 7.5 | 59.2 | Adv. Funct. Mater. 2015, 25, |
| | | | | 5548-5556 |
| DTzSCz | 12.5 | 3.9 | 68.8 | J. Mater. Chem. C, 2016, 4, |
| | | | | 7260-7268 |

It can be seen from Table 4 that it is exhibited slower decay after m-BPySCz is applied to electroluminescent sky-blue light-emitting devices with similar structure.

(2) The data of unencapsulated green light-emitting devices, the result of comparison as following Table 5:

TABLE 5

| | η_{ext, max} | η_{ext, 1000} | Δη₁₀₀₀ | |
|---|---|---|---|---|
| Host | (%) | (%) | (%) | References |
| m-BPySCz | 28.0 | 26.7 | 4.6 | present disclosure |
| TPOTP | 25.2% | 23.3% | 7.5 | J. Mater. Chem. C, 2015, 3, |
| | | | | 1491-1496 |
| 3-CzDPz | 29.0 | 26.6 | 8.3 | ACS Appl. Mater. Interfaces |
| | | | | 2015, 7, 26206-26216 |
| mCPDPz | 18.6 | 16.9 | 9.1 | ACS Appl. Mater. Interfaces |
| | | | | 2015, 7, 26206-26216 |
| o-CzPyPz | 20.9 | 18.9 | 9.6 | ACS Appl. Mater. Interfaces |
| | | | | 2016, 8, 22382-22391 |
| PPI-F-TPA | 15.6 | 13.9 | 10.9 | J. Mater. Chem. C, 2016, 4, |
| | | | | 2003-2010 |
| m-PyPOmCP | 24.4 | 21.7 | 11.1 | Chem. Sci., 2016, 7, |
| | | | | 6706-6714 |
| p-PyPOmCP | 28.2 | 22.7 | 19.5 | Chem. Sci., 2016, 7, |
| | | | | 6706-6714 |
| m-CzDPz | 26.3 | 20.4 | 22.4 | ACS Appl. Mater. Interfaces |
| | | | | 2015, 7, 26206-26216 |
| m-PyCNmCP | 18.4 | 14.2 | 22.8 | ACS Appl. Mater. Interfaces |
| | | | | 2016, 8, 21497-21504 |
| m-CzPyPz | 23.3 | 16.7 | 28.3 | ACS Appl. Mater. Interfaces |
| | | | | 2016, 8, 22382-22391 |
| p-CzPyPz | 27.32 | 19.4 | 29.0 | ACS Appl. Mater. Interfaces |
| | | | | 2016, 8, 22382-22391 |
| 3-PyCNmCP | 24.7 | 16.8 | 32.0 | ACS Appl. Mater. Interfaces |
| | | | | 2016, 8, 21497-21504 |
| 3CzPyaPy | 17.7 | 9.1 | 48.6 | ACS Appl. Mater. Interfaces |
| | | | | 2017, 9, 26242-26251 |
| ICDP | 8.3 | 3.6 | 56.6 | Adv. Funct. Mater. 2015, 25, |
| | | | | 5548-5556 |
| 4ICPPy | 23.2 | 3.3 | 85.8 | Adv. Funct. Mater. 2015, 25, |
| | | | | 5548-5556 |
| 4ICDPy | 26.4 | 4.3 | 83.7 | Adv. Funct. Mater. 2015, 25, |
| | | | | 5548-5556 |

As can be seen from Table 5, this electroluminescent material m-BPySCz has higher efficiency and slower decay than most of green light-emitting devices with similar structure described in prior art.

What is claimed is:

1. An organic electroluminescent material being a compound having structure of formula I:

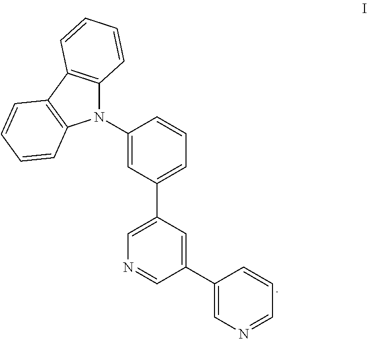 [SMILES: c1cncc(-c2cncc(-c3cccc(-n4c5ccccc5c5ccccc54)c3)c2)c1]

2. An organic electroluminescent device, comprising a light emitting layer, wherein, the light emitting layer contains the organic electroluminescent material described in claim 1.
